(19) United States
(12) Patent Application Publication
(10) Pub. No.: US 2004/0161006 A1
(43) Pub. Date: Aug. 19, 2004

(54) Method and apparatus for improving wavelength stability for InGaAsN devices

(76) Inventors: Ying-Lan Chang, Cupertino, CA (US); Tetsuya Takeuchi, Sunnyvale, CA (US); Danny E. Mars, Los Altos, CA (US); David P. Bour, Cupertino, CA (US); Michael R.T. Tan, Menlo Park, CA (US)

Correspondence Address: AGILENT TECHNOLOGIES, INC., Legal Department, DL429, Intellectual Property Administration, P.O. Box 7599, Loveland, CO, 80537-0599, US

(21) Appl. No.: 10/368,502

(22) Filed: Feb. 18, 2003

(51) Int. Cl. H01S 5/00

(52) U.S. Cl. 372/45

(57) ABSTRACT

An InGaAsN semiconductor light-emitting device containing one or more barrier layers is designed to prevent diffusion of one or more elements out of the quantum well. In one embodiment, the barrier layer can either contain nitrogen in substantially the same concentration as the InGaAsN layer or contain two or more group III elements in combination with nitrogen, where the fractional composition of the two or more group III elements and nitrogen is designed to minimize out-diffusion of nitrogen from the quantum well. In other embodiments, the barrier layer can contain indium and gallium to minimize In/Ga intermixing at the heterointerface to the quantum well. In further embodiments, a compressive-strained or lattice-matched intermediate layer can be added between the InGaAsN quantum well and a tensile-strained barrier layer to minimize strain-related out-diffusion of nitrogen.

### BACKGROUND OF THE INVENTION

1. Technical Field of the Invention

The present invention relates generally to InGaAsN devices, and specifically to improving wavelength stability in InGaAsN semiconductor lasers.

2. Description of Related Art

Vertical-Cavity Surface-Emitting Lasers (VCSELs), Edge Emitting Lasers (EELs) and other types of semiconductor light emitting devices, such as quantum cascade lasers and light emitting diodes (LEDs), are becoming increasingly important for a wide variety of applications, including optical interconnect systems, optical computing systems and telecommunications systems. For high-speed optical fiber communications, emission wavelengths in the 1.2 to 1.6 μm range are desired. Various approaches to fabricating semiconductor light emitting devices in the 1.2 to 1.6 μm range have included using InGaAsP lattice matched to InP, wafer bonding of AlAs/GaAs to InP-based materials, using thallium compounds and using antimony compounds.

Recently, group III-nitride-arsenides (e.g., InGaAsN) have become promising materials for 1.2 to 1.6 μm optoelectronic devices grown on gallium arsenide (GaAs) substrates. Rapid thermal annealing of InGaAsN significantly improves the photoluminescence of InGaAsN materials, making InGaAsN a viable material for use in optoelectronic applications. However, the annealing process also produces a blue shift in the emission wavelength of InGaAsN materials.

The resulting blue shift has been largely attributed to nitrogen diffusing out of the quantum well. For example, in an article by Li et al., entitled “Effects of rapid thermal annealing on the optical properties of GaNₓAs₁₋ₓ/GAAs single quantum well structure grown by molecular beam epitaxy” J. Appl. Phys. 87, p. 245 (2000), which is hereby incorporated by reference, the authors conclude that the blue shift in the emission wavelength after anneal is a result of N-As atomic interdiffusion across the heterointerface due to the concentration gradient of nitrogen between the quantum well and surrounding layers.

However, other factors, such as the out-diffusion of nitrogen from the quantum well due to strain fields and indium and gallium intermixing at the heterointerface, have also been considered as potential sources of the blue shift in wavelength emission after annealing. For example, in an article by Chang et al., entitled “Study of hydrogenation on near-surface strained and unstrained quantum wells,” J. Appl. Phys. 75, 3040 (1994), which is hereby incorporated by reference, the authors observed a hydrogen pile-up effect at InGaAs/GaAs interfaces, suggesting that hydrogen reaching the well prefers diffusing into the barrier to lower the system strain energy. Due to the small atomic size of nitrogen, similar reasoning can also be applied to the cause of out-diffusion of nitrogen from the quantum well.

As another example, in an article by Mars et al., entitled “Growth of 1.2 μm InGaAsN laser material on GaAs by molecular beam epitaxy,” J. Vac. Sci. Technol. B17, 1272 (1999), which is hereby incorporated by reference, the authors found that post-growth annealing can also cause a blue shift for InGaAs/GaAs quantum wells. The blue shift seen in InGaAsN materials after post-growth annealing may be able to be attributed to In/Ga intermixing at the heterointerface.

Currently, there does not exist any mechanism for compensating for the blue shift in emission wavelength in annealed InGaAsN/GaAs materials. Therefore, what is needed is an InGaAsN/GaAs material structure capable of emitting in the 1.2 to 1.6 μm range after annealing.

### SUMMARY OF THE INVENTION

Embodiments of the present invention provide a method and apparatus for improving the wavelength stability of InGaAsN materials utilizing one or more barrier layers to minimize diffusion of one or more elements out of the quantum well. In one embodiment, a barrier layer of a material containing nitrogen in substantially the same concentration as in the InGaAsN layer is provided adjacent to the InGaAsN layer to minimize out-diffusion of nitrogen from the quantum well, while maintaining electron confinement. In other embodiments, the material of the barrier layer may contain two or more group III elements and nitrogen, where the fractional composition of the two or more group III elements and nitrogen is designed to minimize out-diffusion of nitrogen from the quantum well.

In further embodiments, the material of the barrier layer can contain indium and gallium to minimize In/Ga intermixing at the heterointerface to the quantum well. The In/Ga barrier layer can further be doped with nitrogen to minimize out-diffusion of nitrogen as well as minimizing the intermixing of indium and gallium.

In still further embodiments, a compressive-strained intermediate layer can be located between the InGaAsN quantum well and a tensile-strained barrier layer to minimize strain-related out-diffusion of nitrogen. The tensile-strained barrier layer may be designed to minimize out-diffusion of nitrogen and/or In/Ga intermixing by containing nitrogen and/or indium and gallium.

By incorporating one or more barrier layers having a composition designed to minimize out-diffusion of one or more elements from the InGaAsN quantum well, the blue shift in emission wavelength of annealed InGaAsN materials may be reduced. As a result, an InGaAsN/barrier layer/GaAs material structure may be capable of emitting in the 1.2 to 1.6 μm range after annealing. Furthermore, the invention provides embodiments with other features and advantages in addition to or in lieu of those discussed above. Many of these features and advantages are apparent from the description below with reference to the following drawings.

### BRIEF DESCRIPTION OF THE DRAWINGS

The disclosed invention will be described with reference to the accompanying drawings, which show important sample embodiments of the invention and which are incorporated in the specification hereof by reference, wherein:

FIG. 1 is a simplified cross-sectional view illustrating an exemplary semiconductor light-emitting structure, in accordance with one embodiment of the present invention,

FIG. 2 is a schematic representation of a first exemplary active region of the semiconductor light-emitting structure of FIG. 1;

FIG. 3 is a flow chart illustrating exemplary simplified blocks for fabricating a semiconductor light-emitting structure having an active region as shown in FIG. 2;

FIG. 4 is a schematic representation of a second exemplary active region of the semiconductor light-emitting structure of FIG. 1;

FIG. 5 is a flow chart illustrating exemplary simplified blocks for fabricating a semiconductor light-emitting structure having an active region as shown in FIG. 4;

FIG. 6 is a simplified cross-sectional view illustrating another exemplary semiconductor light-emitting structure, in accordance with another embodiment of the present invention;

FIG. 7 is a schematic representation of an exemplary active region of the semiconductor light-emitting structure of FIG. 6;

FIG. 8 is a flow chart illustrating exemplary simplified blocks for fabricating a semiconductor light-emitting structure having an active region as shown in FIG. 7; and

FIGS. 9A and 9B illustrate exemplary semiconductor light-emitting devices having the structure of FIG. 1 or FIG. 6, in accordance with embodiments of the present invention.

### DETAILED DESCRIPTION OF THE EXEMPLARY EMBODIMENTS

The numerous innovative teachings of the present application will be described with particular reference to the exemplary embodiments. However, it should be understood that these embodiments provide only a few examples of the many advantageous uses of the innovative teachings herein. In general, statements made in the specification do not necessarily delimit any of the various claimed inventions. Moreover, some statements may apply to some inventive features, but not to others.

All concentrations for chemical elements are provided below in ratios which range from 0.0 to 1.0, where 1.0 corresponds to 100% of an element group containing that element. For example, when discussing a group III or group V semiconductor material, the ratio applies to the concentration of the elements in either the group III material or the group V material and not the entire semiconductor material. In addition, all concentrations disclosed herein are approximate values, regardless of whether the word “about” or “approximate” is used in connection therewith. The concentrations may vary by up to 1 mol percent, 2 mol percent, 5 mol percent or up to 10-20 mol percent from that which is described, where a mol percent is a percentage expressed in terms of moles, rather than weight. Further, as used herein, the terms “substantially equal” and “substantially the same” mean that a concentration difference between adjacent layers is not more than 10 mol percent to about 200 mol percent.

Embodiments of the present invention provide semiconductor light-emitting structures in which the atomic mobility is reduced or eliminated. In some embodiments, the atomic mobility is reduced by reducing the concentration gradients at or near an interface between the quantum well and a barrier layer. In other embodiments, an intermediate compressively-strained barrier layer reduces mobility induced due to lattice mismatch between the quantum well and a tensile-strained barrier layer.

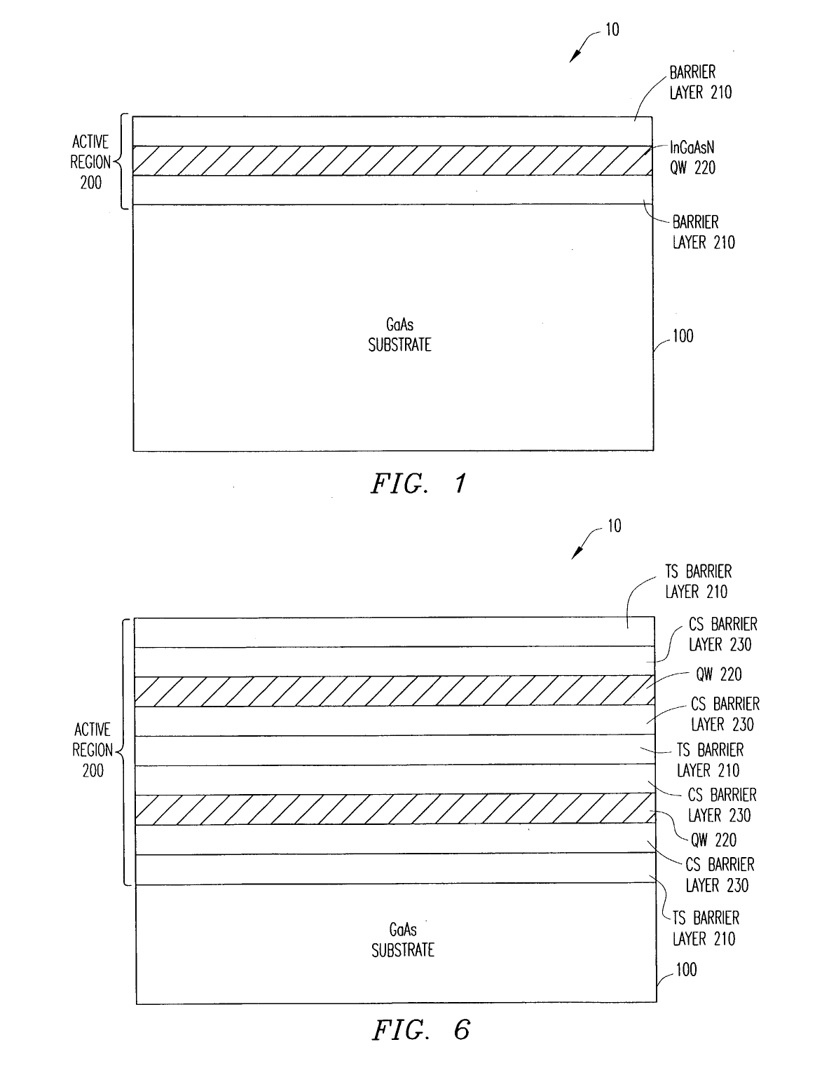

FIG. 1 shows a simplified cross-sectional view illustrating an exemplary semiconductor light-emitting structure 10 capable of emitting in the 1.2 μm to 1.5 μm range after annealing of the structure 10, in accordance with one embodiment of the present invention. The semiconductor light-emitting structure 10 can be a part of any light-emitting device. By way of example, but not limitation, the light-emitting device can be a vertical-cavity surface-emitting laser (VCSEL), edge emitting laser (EEL), quantum cascade laser or light emitting diode (LED).

The structure 10 includes a substrate 100 formed of a semiconductor material consisting of Ga and As and an active region 200 containing an InGaAsN light-emitting quantum well 220. It should be appreciated that the substrate 100 may include any material underneath the active region 200. For example, mirror layers, waveguide layers and cladding layers may form a part of the substrate 100. The InGaAsN quantum well 220 has a thickness ranging from approximately 4 nanometers (nm) to approximately 10 nm, with an indium concentration of 30%-45% and a nitrogen concentration of 0.5%-4%. For example, in one embodiment, the quantum well material can be In_{0.35}Ga_{0.65}As_{0.099}N_{0.01}.

The active region 200 further includes one or more barrier layers 210 on either side of the InGaAsN quantum well 220. Each barrier layer 210 has a thickness ranging from approximately 5 nm to approximately 20 nm. The barrier layers 210 have a composition designed to minimize diffusion of one or more elements out of the quantum well 220 in order to reduce the blue shift in emission wavelength resulting from the annealing process. The InGaAsN quantum well 220 and barrier layers 210 can be pseudomorphically grown on the GaAs substrate 100 using any known epitaxial growth technique. For example, such techniques include, but are not limited to, MBE, MOVPE, MOCVD or MOMBE. The InGaAsN quantum well 220 can have either a single quantum well (SQW) structure or a multiple quantum well (MQW) structure. In a MQW structure, at least one barrier layer 210 is provided between each of the quantum well layers 220.

In one embodiment, the barrier layer 210 is designed to minimize the diffusion of nitrogen out of the quantum well 220. For example, the barrier layer 210 can be a Group III-V nitride. By including nitrogen in the barrier layer 210, the nitrogen concentration gradient between the quantum well 220 and the surrounding material is reduced, thereby decreasing the tendency for nitrogen to diffuse out of the quantum well 220 during thermal processing of the structure 10.

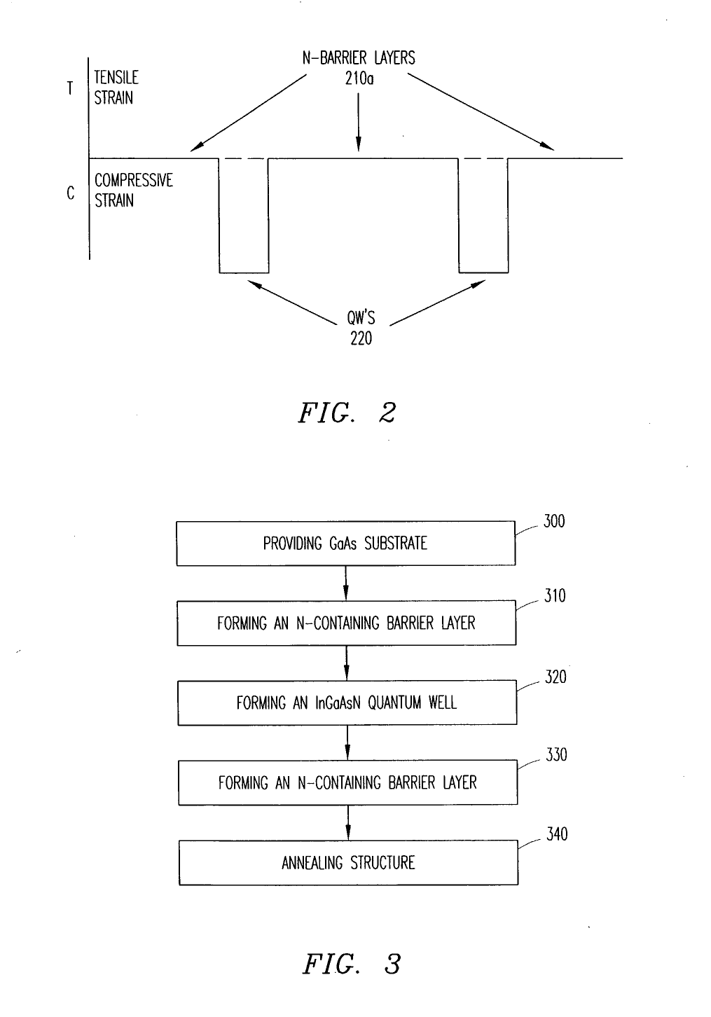

FIG. 2 is a schematic representation of an exemplary active region of the semiconductor light-emitting device structure of FIG. 1. In FIG. 2, the vertical axis represents the lattice constant of the growth material, with the horizontal axis positioned at the lattice constant of the substrate. The horizontal axis represents the growth direction. As can be seen in FIG. 2, surrounding the InGaAsN quantum wells 220 are N-containing barrier layers 210a that are substantially lattice-matched to the GaAs substrate.

In one embodiment, the nitrogen concentration of the barrier layer 210a material is substantially equal to or greater than the nitrogen concentration as the InGaAsN quantum well 220 to effectively prevent out-diffusion of nitrogen from the quantum well 220, while maintaining electron confinement. For example, the material of the barrier layer 210a can be a GaAsN material, having a nitrogen concentration substantially equal to or greater than the nitrogen concentration in the material of the quantum well 220.

In other embodiments, the material of the barrier layer 210a can contain two or more group III elements in combination with nitrogen, where the concentration of the two or more group III elements and nitrogen is designed to minimize out-diffusion of nitrogen from the quantum well 220. The material of the barrier layer 210a can be either compressively strained, tensile strained or substantially lattice-matched to the GaAs substrate. If the material of the barrier layer 210a is mismatched (compressive or tensile), the strain can be up to three percent. For example, the material of the barrier layer 210a can be InGaAsN materials, AlGaAsN materials, AlInGaAsN materials, InGaPN materials, AlInGaPN materials, AlInGaAsPN materials or any other combination of two or more group III elements and one or more group V elements and nitrogen. An example of a barrier layer material with a composition capable of minimizing nitrogen out-diffusion and substantially lattice-matched to the GaAs substrate is In_{0.5}Ga_{0.5}P_{0.99}N_{0.1}.

FIG. 3 is a flow chart illustrating a simplified exemplary process for fabricating a semiconductor light-emitting structure having an active region as shown in FIG. 2. To form the light-emitting structure, a first barrier layer containing nitrogen in sufficient concentration to minimize out-diffusion of nitrogen from the quantum well is formed above a substrate (blocks 300 and 310). By way of example, the substrate is a semiconductor substrate containing gallium arsenide (GaAs) doped with an impurity material or dopant of the N conductivity type, such as silicon. The first barrier layer may be epitaxially grown above the substrate using, for example, MBE, MOVPE, MOCVD or MOMBE, and has a thickness ranging from approximately 5 nm to approximately 20 nm.

A light-emitting quantum well layer containing InGaAsN is formed over the first barrier layer (block 320) using any epitaxial growth technique. The InGaAsN quantum well has a thickness ranging from approximately 4 nm to approximately 10 nm, with an indium concentration of 30%-45% and a nitrogen concentration of 0.5%-4%. A second barrier layer having substantially the same composition and thickness as the first barrier layer is formed over the InGaAsN quantum well (block 330), using any epitaxial growth technique. The N-containing barrier layers serve to reduce out-diffusion of nitrogen from the quantum well during an annealing process (block 340), which is performed to improve the photoluminescence (PL) of InGaAsN materials. Reducing or eliminating the out-diffusion of nitrogen reduces the blue shift in the emission wavelength of the annealed InGaAsN material. As a result, the InGaAsN material may be capable of emitting in the 1.2 to 1.6 μm range after annealing.

In further embodiments, the barrier layer is composed of a Group III-V compound that includes both indium and gallium to minimize In/Ga intermixing at the heterointerface to the quantum well. FIG. 4 is a schematic representation of a second exemplary active region of the semiconductor light-emitting structure of FIG. 1. As can be seen in FIG. 4, on either side of the InGaAsN quantum wells 220 are In/Ga-containing barrier layers 210b that are substantially lattice-matched to or slightly tensile strained in comparison with the GaAs substrate.

In one embodiment, the indium concentration in the material of the barrier layer 210b is substantially equal to or greater than the indium concentration as the InGaAsN quantum well 220 to minimize intermixing of indium and gallium at the heterointerface to the quantum well 220. For example, the material of the barrier layer 210b can be composed of InGaP materials, AlInGaP materials, InGaAsP materials, AlInGaAsP materials or any other material containing In and Ga in sufficient concentration to minimize In/Ga intermixing and to be substantially lattice-matched to or slightly tensile strained in comparison with the GaAs substrate. An example of a barrier layer material with a composition capable of minimizing In/Ga intermixing that is substantially lattice-matched to the GaAs substrate is In_{0.5}Ga_{0.5}P.

In other embodiments, the material of the In/Ga barrier layer 210b can further be doped with nitrogen to minimize out-diffusion of nitrogen as well as minimizing the intermixing of indium and gallium. For example, the material of the barrier layer 210b can be InGaAsN or any other material containing In, Ga and N in sufficient concentration to minimize In/Ga intermixing and out-diffusion of nitrogen from the quantum well 220 and to be substantially lattice-matched to or slightly tensile strained in comparison with the GaAs substrate.

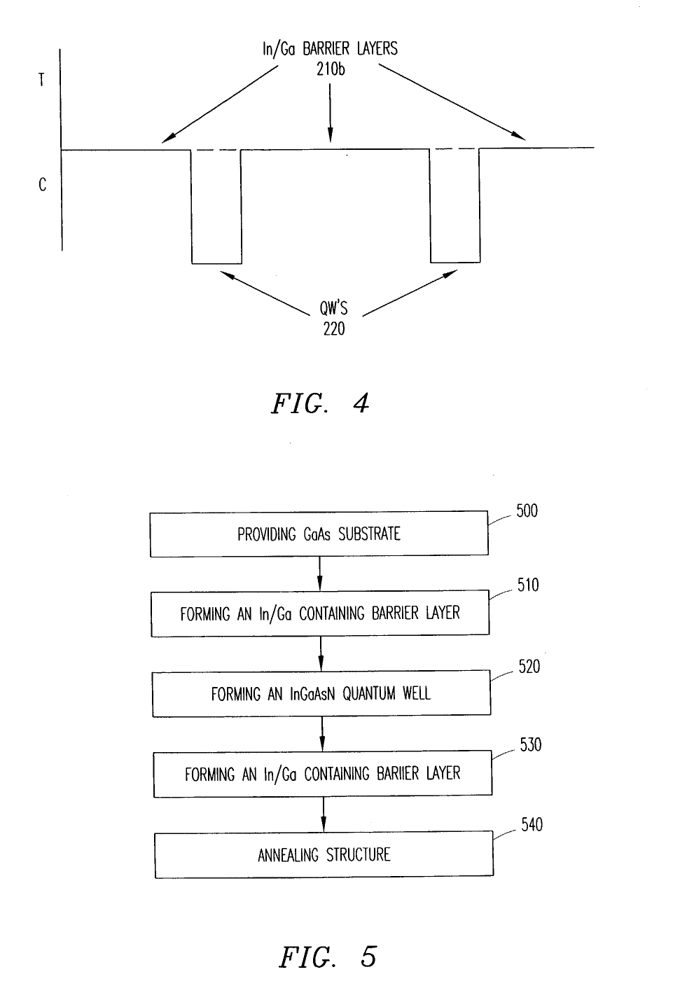

FIG. 5 is a flow chart illustrating a simplified exemplary process for fabricating a semiconductor light-emitting structure having an active region as shown in FIG. 4. To form the light-emitting structure, a first barrier layer containing indium in sufficient concentration to minimize In/Ga intermixing at the heterointerface to the quantum well is formed above a substrate (blocks 500 and 510). By way of example, the substrate is a semiconductor substrate containing gallium arsenide (GaAs) doped with an impurity material or dopant of the n conductivity type, such as silicon. The first barrier layer may be epitaxially grown above the substrate using, for example, MBE, MOVPE, MOCVD or MOMBE, and has a thickness ranging from approximately 5 nm to approximately 20 nm.

A light-emitting quantum well layer containing InGaAsN is formed over the first barrier layer (block 520), using any epitaxial growth technique. The InGaAsN quantum well has a thickness ranging from approximately 4 nm to approximately 10 nm, with an indium concentration of 30%-45% and a nitrogen concentration of 0.5%-4%. A second barrier layer having substantially the same composition and thickness as the first barrier layer is formed over the InGaAsN quantum well (block 530), using any epitaxial growth technique. The In-containing barrier layers serve to reduce In/Ga intermixing during an annealing process (block 540) to enable the InGaAsN material to emit light in the 1.2 to 1.6 μm range after annealing.

FIG. 6 is a simplified cross-sectional view illustrating another exemplary semiconductor light-emitting structure 10 capable of emitting in the 1.2 μm to 1.5 μm range after annealing of the structure 10, in accordance with one embodiment of the present invention. As in FIG. 1, the semiconductor light-emitting structure 10 can be a part of any light-emitting device. By way of example, but not limitation, the light-emitting device can be a vertical-cavity surface-emitting laser (VCSEL), edge emitting laser (EEL), quantum cascade laser or light emitting diode (LED).

The structure 10 includes a substrate 100 formed of a semiconductor material consisting of Ga and As and an active region 200 containing one or more InGaAsN light-emitting quantum wells 220. It should be appreciated that the substrate 100 may include any material underneath the active region. For example, mirror layers, waveguide layers and cladding layers may form a part of the substrate 100. Each InGaAsN quantum well 220 has a thickness ranging from approximately 4 nm to approximately 10 nm, with an indium concentration of 30%-45% and a nitrogen concentration of 0.5%-4%. For example, in one embodiment, the quantum well material can be In_{0.35}Ga_{0.65}As_{0.99}N_{0.01}.

The active region 200 further includes a tensile-strained barrier layer 210 and a compressive-strained intermediate barrier layer 230 between the InGaAsN quantum well 220 and the tensile-strained barrier layer 210. The intermediate barrier layer 230 serves to reduce the strain difference between the quantum well 220 and the tensile-strained barrier layer 210. The compressive-strained intermediate barrier layers 230 and tensile-strained barrier layers 210 each have a thickness ranging from approximately 2.5 nm to approximately 30 nm. The compressive-strained intermediate barrier layers 230 have a composition designed to minimize strain-related out-diffusion of nitrogen from the quantum well 220 in order to reduce the blue shift in emission wavelength resulting from the annealing process. The tensile-strained barrier layers 210 may additionally be designed to minimize out-diffusion of nitrogen and/or In/Ga intermixing by containing nitrogen and/or indium and gallium, as described above in connection with FIGS. 2 and 4. For example, the compressive-strained intermediate barrier layers 230 and tensile-strained barrier layers 210 can each be individually formed of a Group III-V nitride, a Group III-V phosphide, a Group-V arsenide, or a Group III-V nitride phosphide having an appropriate lattice constant.

The material of the quantum well 220 and the material of the compressive-strained intermediate barrier layer 230 both have a lattice constant larger than that of the substrate 100, while the material of the tensile-strained barrier layer 210 has a lattice constant less than that of the substrate 100. The lattice constant of a barrier layer material is controlled by appropriately choosing the concentrations of the different elements. For example, when a larger lattice constant is desired, the concentration of an element having a larger atomic radius can be increased. Likewise, when a smaller lattice constant is desired, the concentration of one or more larger atomic radius element can be decreased with a corresponding increase in one or more smaller atomic radius elements, while maintaining electro-neutrality in the material.

The InGaAsN quantum well 220 and barrier layers 210 and 230 can be pseudomorphically grown on the GaAs substrate 100 using any known epitaxial growth technique, such as MBE, MOVPE, MOCVD or MOMBE. The InGaAsN quantum well 220 can have either a single quantum well (SQW) structure or a multiple quantum well (MQW) structure, the latter being shown in FIG. 6. In the MQW structure, a separate compressive-strained intermediate barrier layer 230 is provided on either side of each quantum well 220 and a separate tensile-strained barrier layer 210 is provided separating the compressive-strained intermediate barrier layers 230. By providing a compressive-strained intermediate barrier layer 230, there is a smaller difference in strain between the quantum well 220 and the intermediate barrier layer 230, thereby decreasing the tendency for nitrogen to diffuse out of the quantum well 220 during thermal processing of the structure 10.

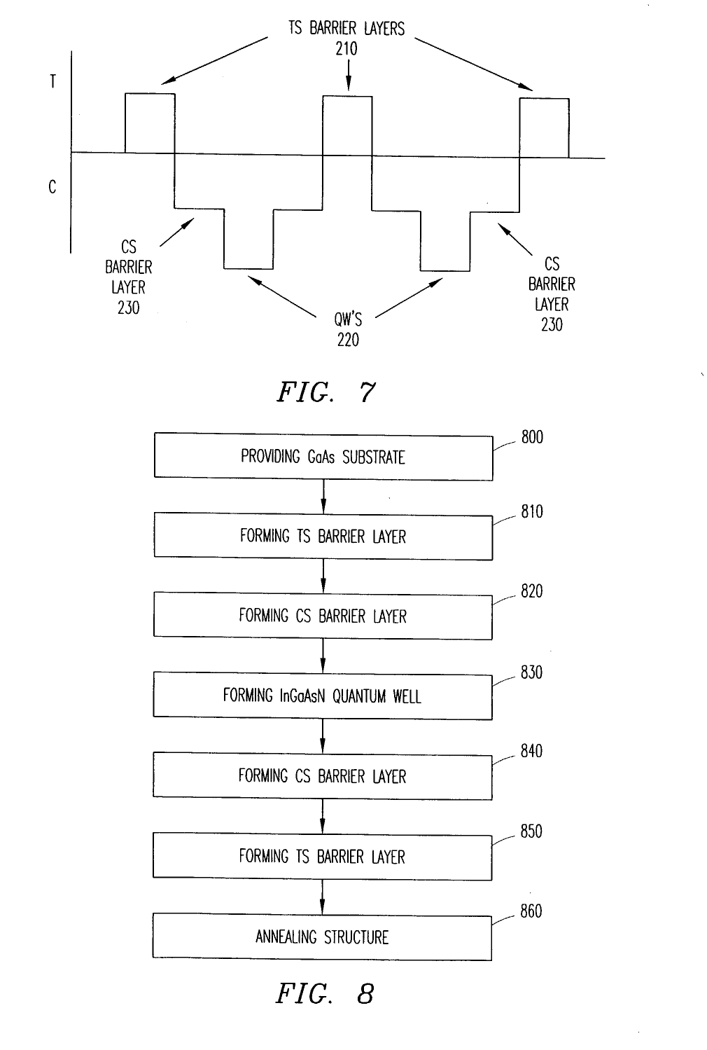

FIG. 7 is a schematic representation of an exemplary active region of the semiconductor light-emitting device structure of FIG. 6. In FIG. 7, the vertical axis represents the lattice constant of the growth material, with the horizontal axis positioned at the lattice constant of the substrate. The horizontal axis represents the growth direction. As can be seen in FIG. 7, surrounding the InGaAsN quantum wells 220 are intermediate barrier layers 230 that are compressively strained in comparison with the GaAs substrate. For example, the compressive-strained barrier layer 230 material can be composed of compressive-strained InGaP materials, InGaAsN materials, AlInGaP materials, InGaAsP materials, AlInGaAsP materials or any other combination of elements that produces a compressive-strained material. An example of a barrier layer material for the compressive-strained intermediate layer 230 sufficient to minimize strain-related nitrogen out-diffusion is In_{0.5}Ga_{0.5}As_{0.2}P_{0.8}.

Separating the compressive-strained intermediate barrier layers 230 are tensile-strained barrier layers 210 designed to compensate for the compressive-strained quantum well 220 and intermediate layer 230. In addition, the tensile-strained barrier layers 210 can be further designed to help minimize out-diffusion of nitrogen and/or In/Ga intermixing by containing nitrogen and/or indium and gallium. For example, the tensile-strained barrier layer 210 material can be composed of tensile-strained GaAsP materials, InGaP materials, AlInGaP materials, InGaAsP materials, AlInGaAsP materials, InGaAsN materials, GaAsN materials or any other combination of elements that produces a tensile-strained material. An example of a barrier layer material for the tensile-strained barrier layer 210 is In_{0.4}Ga_{0.6}P.

FIG. 8 is a flow chart illustrating a simplified exemplary process for fabricating a semiconductor light-emitting structure having an active region as shown in FIG. 7. To form the light-emitting structure, a first tensile-strained barrier layer designed to compensate for the compressively-strained quantum well is formed above a substrate (blocks 800 and 810). By way of example, the substrate is a semiconductor substrate containing gallium arsenide (GaAs) doped with an impurity material or dopant of the N conductivity type, such as silicon. The first tensile-strained barrier layer may be epitaxially grown above the substrate using, for example, MBE, MOVPE, MOCVD or MOMBE, and has a thickness ranging from approximately 5 nm to approximately 20 nm.

A first compressive-strained intermediate barrier layer is formed above the first tensile-strained barrier layer (block 820), using, for example, MBE, MOVPE, MOCVD or MOMBE, and has a thickness ranging from approximately 2.5 nm to approximately 30 nm. A light-emitting quantum well layer containing InGaAsN is formed over the first compressive-strained barrier layer (block 830) using any epitaxial growth technique. The InGaAsN quantum well has a thickness ranging from approximately 4 nm to approximately 10 nm, with an indium concentration of 30%-45% and a nitrogen concentration of 0.5%-4%.

A second compressive-strained intermediate barrier layer having substantially the same composition and thickness as the first compressive-strained barrier layer is formed over the InGaAsN quantum well (block 840), using any epitaxial growth technique. A second tensile-strained barrier layer having substantially the same composition and thickness as the first tensile-strained barrier layer is formed over the second compressive-strained intermediate barrier layer (block 850), using any epitaxial growth technique. The compressive-strained intermediate barrier layers serve to reduce out-diffusion of nitrogen from the quantum well during an annealing process (block 860) to enable the InGaAsN material to emit light in the 1.2 to 1.6 μm range after annealing.

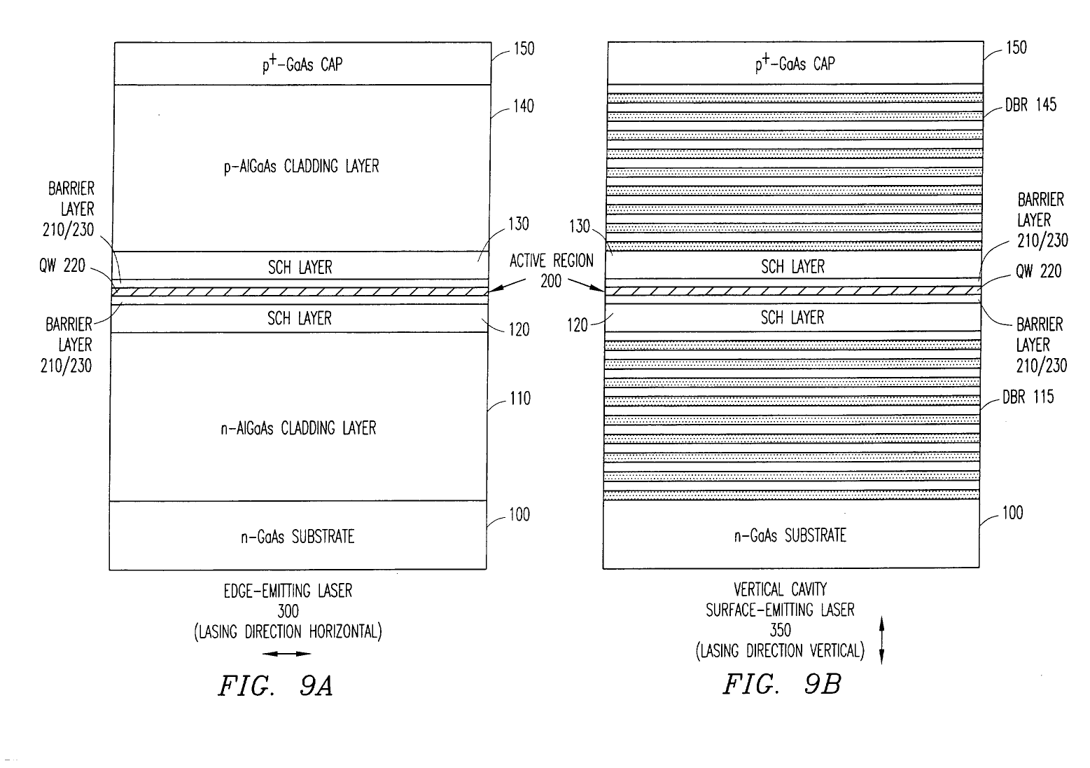

FIGS. 9A and 9B illustrate exemplary semiconductor light-emitting devices having the structure of FIG. 1 or FIG. 6, in accordance with embodiments of the present invention. Referring now to FIG. 9A, there is illustrated an exemplary edge-emitting laser 300 formed with the active region 200 structure shown in FIG. 1 or FIG. 6. The edge-emitting laser 300 includes a single crystal substrate 100 formed of gallium arsenide. The substrate 100 can be doped with, for example, an n-type dopant, such as silicon. The substrate 100 can range in thickness from about 100 μm to about 500 μm.

A cladding layer 110 having a thickness ranging between about 0.5 μm and about 5 μm is formed on the substrate 100. A suitable material for the cladding layer 110 is aluminum gallium arsenide (AlGaAs). By way of example, the cladding layer 110 can be Al_{0.5}Ga_{0.5}As doped with an n-type dopant having a concentration of approximately 10¹⁸ atoms/cm³. The mole fraction of aluminum in the cladding layer 110 can range from approximately 0.2 to approximately 0.9.

A confinement or undoped layer 120 having a thickness ranging between approximately 20 nm and approximately 500 nm is formed on the cladding layer 110. The confinement layers 120 and 130 are also referred to as a Separate Confinement Heterostructure (SCH). A suitable material for the SCH layer 120 has a lower bandgap than that of the cladding layer 110 and a higher bandgap than that of the quantum well(s) 220 in the active region 200 disposed over the SCH layer 120. For example, the SCH layer 120 can be Al_{0.3}Ga_{0.7}As. The mole fraction of aluminum in the SCH layer 120 can range from 0 to approximately 0.5. The SCH layer 120 is also referred to as an n-side SCH layer.

An active region 200 having a thickness ranging between about 16 and about 300 nm is formed over the n-side SCH layer 120. The active region 200 includes one or more InGaAsN quantum well layers 220, each having a thickness ranging from approximately 4 nm to approximately 10 nm, and one or more barrier layers 210/230 separating the quantum well layers 220, where each of the barrier layers 210/230 has a thickness ranging from approximately 5 nm to approximately 20 nm. By way of example, the active region 200 includes one InGaAsN quantum well layer 220 separated by barrier layers 210/230, each of which can contain one or more layers, as described above. Thus, a first barrier layer 210/230 is formed over the SCH layer 120, the InGaAsN quantum well layer 220 is formed over the first barrier layer 210/230 and a second barrier layer 210/230 is formed over the InGaAsN quantum well layer 220.

Each InGaAsN quantum well 220 has an indium concentration of 30%-45% and a nitrogen concentration of 0.5%-4%. For example, in one embodiment, the quantum well material can be In_{0.35}Ga_{0.65}As_{0.99}N_{0.01}. Each barrier layer 210/230 is formed of one or more layers of a Group III-V nitride, a Group III-V phosphide, a Group III-V arsenide or a Group III-V nitride phosphide, in which each barrier layer 210/230 is designed to minimize out-diffusion of one or more elements from the quantum well 220, as described above in connection with FIGS. 1-8.

A p-side SCH layer 130 having a thickness ranging between approximately 20 nm and approximately 500 nm is formed on the active region 200. The p-side SCH layer 130 is an undoped cladding layer. A suitable material for the p-side SCH layer 130 has a wider bandgap than that of the quantum well(s) 220 in the active region 200 and a lower bandgap than that of a p-type cladding layer 140 disposed over the p-side SCH layer 130. For example, the p-side SCH layer 130 can be Al_{0.3}Ga_{0.7}As. The mole fraction of aluminum in the p-side SCH layer 130 can range from 0 to 0.5.

A p-type cladding layer 140 having a thickness ranging between about 0.5 μm and about 5 μm is formed over the p-side SCH layer 130. A suitable material for the p-type cladding layer 140 is aluminum gallium arsenide (AlGaAs). By way of example, the p-type cladding layer 140 can be Al_{0.5}Ga_{0.5}As doped with a p-type dopant having a concentration of approximately 5×10¹⁷ atoms/cm³. The mole fraction of aluminum in the p-type cladding layer 140 can range from approximately 0.2 to approximately 0.9.

A capping layer 150 having a thickness ranging between approximately 5 nm and approximately 500 nm is formed over the p-type cladding layer 140 to serve as a contact layer. A suitable material for the capping layer 150 is gallium arsenide (GaAs) that is highly p-doped and of a lower band gap energy than the p-type cladding layer 140. This provides a lower Schottky barrier at the interface between the capping layer 150 and a metal electrode (not shown) formed thereon. By way of example, the capping layer 150 can be GaAs doped with a p-type dopant having a concentration greater than approximately 1×10¹⁹ atoms/cm³. All of the layers described above can be formed using any conventional or other suitable technique, such as MBE, MOVPE, MOCVD or MOMBE.

Referring now to FIG. 9B, there is illustrated an exemplary vertical-cavity surface-emitting laser (VCSEL) 350 formed with the active region 200 structure shown in FIG. 1 or FIG. 6. The VCSEL 350 includes a single crystal substrate 100 formed of gallium arsenide. The substrate 100 can be doped with, for example, an n-type dopant, such as silicon. The substrate 100 can range in thickness from about 100 μm to about 500 μm.

A first quarter wave stack 115 having a thickness ranging between about 0.5 μm and about 100 μm is formed on the substrate 100. The first quarter wave stack is also referred to as a mirror stack or a distributed Bragg reflector (DBR). A VCSEL 350 is typically fabricated to operate at a particular wavelength, referred to as the lasing wavelength. To enable the VSCEL 350 to emit light at the lasing wavelength, the DBR 115 material is typically transparent at the lasing wavelength. Usually, the first DBR 115 contains alternating layers of different n-type materials. Suitable materials for the n-type DBR 115 include alternating layers of n-type aluminum arsenide (AlAs) and gallium arsenide (GaAs). In addition, the thickness of each layer can be equal to one-quarter of the lasing wavelength divided by the refractive index. The number of periods of pairs of alternating layers determines the reflectivity of the DBR mirror 115. Typically, the number of periods for the n-type DBR 115 ranges from 30 to 40.

An n-side cavity spacer layer 120 having a thickness ranging between approximately 200 nm and 500 nm is formed on the n-type DBR 115. A suitable material for the cavity spacer layer 120 has a lower bandgap than that of the n-type DBR 115 and a higher bandgap than that of the quantum well(s) 220 in the active region 200 disposed over the n-type cavity spacer layer 120. For example, the cavity space layer 120 can be Al_{0.3}Ga_{0.7}As. The mole fraction of aluminum in the cavity spacer layer 120 can range from 0 to 0.5.

An active region 200 having a thickness ranging between approximately 16 nm and approximately 300 nm is formed over the n-side cavity spacer layer 120. The active region 200 includes one or more InGaAsN quantum well layers 220, each having a thickness ranging from approximately 4 nm to approximately 10 nm, and one or more barrier layers 210/230 separating the quantum well layers 220, where each of the barrier layers 210/230 has a thickness ranging from approximately 5 nm to approximately 20 nm. By way of example, the active region 200 includes one InGaAsN quantum well layer 220 separated by barrier layers 210/230, each of which can contain one or more layers, as described above. Thus, a first barrier layer 210/230 is formed over the cavity spacer layer 120, the InGaAsN quantum well layer 220 is formed over the first barrier layer 210/230 and a second barrier layer 210/230 is formed over the InGaAsN quantum well layer 220.

Each InGaAsN quantum well 220 has an indium concentration of 30%-45% and a nitrogen concentration of 0.5%-4%. For example, in one embodiment, the quantum well 220 material can be In_{0.35}Ga_{0.65}As_{0.99}N_{0.01}. Each barrier layer 210/230 is formed of one or more layers of a Group III-V nitride, a Group III-V phosphide, a Group III-V arsenide, or a Group III-V nitride phosphide, in which each barrier layer 210/230 is designed to minimize out-diffusion of one or more elements from the quantum well 220, as described above in connection with FIGS. 1-8.

A p-side cavity spacer layer 130 having a thickness ranging between approximately 200 nm and approximately 500 nm is formed on the active region 200. The p-side cavity spacer layer 130 is an undoped cladding layer. A suitable material for the p-side cavity spacer layer 130 has a wider bandgap than that of the quantum well(s) 220 in the active region 200 and a lower bandgap than that of a p-type DBR 145 disposed over the p-side cavity spacer layer 130. For example, the p-side cavity spacer layer 130 can be Al_{0.3}Ga_{0.7}As. The mole fraction of aluminum in the p-side cavity spacer layer 130 can range from approximately 0.1 to approximately 0.5.

A p-type DBR 145 having a thickness ranging between about 0.5 μm and about 10 μm is formed over the p-side SCH layer 130. Suitable materials for the p-type DBR 145 include alternating layers of p-type aluminum arsenide (AlAs) and gallium arsenide (GaAs). As with the n-type DBR 115, the thickness of each layer in the p-type DBR 145 can be equal to one-quarter of the lasing wavelength divided by the refractive index. The number of periods of pairs of alternating layers for the p-type DBR 145 ranges from 20 to 25. The n-type DBR 115, cavity spacer layers 120 and 130, active region 200 and p-type DBR 145 form an optical cavity characterized by a cavity resonance at the lasing wavelength.

A capping layer 150 having a thickness ranging between approximately 5 nm and approximately 500 nm is formed over the p-type DBR 145 to serve as a contact layer. A suitable material for the capping layer 150 is gallium arsenide (GaAs) that is highly p-doped and of a lower band gap energy than the p-type DBR 145. This provides a lower Schottky barrier at the interface between the capping layer 150 and a metal electrode (not shown) formed thereon. By way of example, the capping layer 150 can be GaAs doped with a p-type dopant having a concentration greater than approximately 1×10¹⁹ atoms/cm³. All of the layers described above can be formed using any conventional or other suitable technique, such as MBE, MOVPE, MOCVD or MOMBE.

As will be recognized by those skilled in the art, the innovative concepts described in the present application can be modified and varied over a wide range of applications. Accordingly, the scope of patented subject matter should not be limited to any of the specific exemplary teachings discussed, but is instead defined by the following claims.

We claim:

1. A semiconductor light-emitting structure, comprising:
a substrate including gallium arsenide, said substrate having a surface;
a quantum well layer of a material including indium, gallium, arsenic and nitrogen, said quantum well layer being disposed over the surface of said substrate, said quantum well layer having opposing surfaces; and
first and second barrier layers of a barrier material including nitrogen in substantially the same concentration as in said quantum well layer, each of said first and second barrier layers being disposed adjacent to one of said opposing surfaces of said quantum well layer;
wherein said structure is capable of emitting in the 1.2 μm to 1.6 μm range after annealing of said structure.

2. The structure of claim 1, wherein said quantum well layer has a thickness ranging from 4 nm to 10 nm.

3. The structure of claim 1, wherein said quantum well layer has an indium concentration between 30 and 45 percent and a nitrogen concentration between one-half and four percent.

4. The structure of claim 3, wherein said first and second barrier layers are substantially lattice-matched to said substrate.

5. The structure of claim 1, wherein each of said first and second barrier layers has a thickness ranging from 2.5 to 30 nm.

6. The structure of claim 1, wherein said barrier material is selected from the group consisting of Group III-V nitrides.

7. The structure of claim 6, wherein the Group III-V nitrides comprise GaAsN, InGaAsN, AlGaAsN, AlInGaAsN, InGaPN, InGaAsPN, GaAsPN, AlInGaPN and AlInGaAsPN.

8. The structure of claim 1, further comprising:
first and second intermediate barrier layers, each being disposed between said quantum well layer and one of said first and second barrier layers, said first and second intermediate barrier layers each of a compressive-strained or lattice-matched material, said barrier material being a tensile-strained material.

9. The structure of claim 1, wherein said first barrier layer is disposed over said substrate, said quantum well layer is disposed over said first barrier layer and said second barrier layer is disposed over said quantum well layer, and further comprising:
at least one additional quantum well layer disposed over said second barrier layer, said at least one additional quantum well layer including indium, gallium, arsenic and nitrogen; and
at least one additional barrier layer of said barrier material and disposed over said at least one additional quantum well layer.

10. A semiconductor light-emitting structure, comprising:
a substrate including gallium arsenide, said substrate having a surface;
a quantum well layer of a material including indium, gallium, arsenic and nitrogen, said quantum well layer being disposed over the surface of said substrate, said quantum well layer having opposing surfaces; and
first and second barrier layers each of a barrier material including at least two or more Group III elements and nitrogen, each of said first and second barrier layers being disposed adjacent to one of said opposing surfaces of said quantum well layer;
wherein said structure is capable of emitting in the 1.2 μm to 1.6 μm range after annealing of said structure.

11. The structure of claim 10, wherein the fractional composition of the two or more Group III elements and nitrogen in said barrier material is designed to minimize diffusion of nitrogen out of said quantum well layer.

12. The structure of claim 10, wherein said barrier material is selected from the group consisting of InGaAsN, AlGaAsN, AlInGaAsN, InGaPN, InGaAsPN, AlInGaPN and AlInGaAsPN.

13. The structure of claim 10, further comprising:
first and second intermediate barrier layers, each being disposed between said quantum well layer and one of said first and second barrier layers, said first and second intermediate barrier layers each being formed of a compressive-strained material, said barrier material being a tensile-strained material.

14. The structure of claim 10, wherein said first barrier layer is disposed over said substrate, said quantum well layer is disposed over said first barrier layer and said second barrier layer is disposed over said quantum well layer, and further comprising:
at least one additional quantum well layer disposed over said second barrier layer, said at least one additional quantum well layer including indium, gallium, arsenic and nitrogen; and
at least one additional barrier layer of said barrier material and disposed over said at least one additional quantum well layer.

15. A semiconductor light-emitting structure, comprising:
a substrate including gallium arsenide, said substrate having a surface;
a quantum well layer of a material including indium, gallium, arsenic and nitrogen, said quantum well layer being disposed over the surface of said substrate, said quantum well layer having opposing surfaces; and
first and second barrier layers each of a barrier material containing at least indium and gallium, each of said first and second barrier layers being disposed adjacent to one of said opposing surfaces of said quantum well layer,
wherein said structure is capable of emitting in the 1.2 μm to 1.6 μm range after annealing of said structure.

16. The structure of claim 15, wherein said barrier material contains indium and gallium to minimize In/Ga intermixing between said first and second barrier layers and said quantum well.

17. The structure of claim 15, wherein said first and second barrier layers are substantially lattice-matched to said substrate.

18. The structure of claim 15, wherein the concentration of indium in said barrier material is substantially equal to the concentration of indium in said quantum well layer.

19. The structure of claim 15, wherein said barrier material is doped with nitrogen.

20. The structure of claim 15, wherein said barrier material is selected from the group consisting of InGaP, InGaAsN, AlInGaP, InGaAsP, InGaAsPN, and AlInGaAsP.

21. The structure of claim 15, further comprising:
first and second intermediate barrier layers, each being disposed between said quantum well layer and one of said first and second barrier layers, said first and second intermediate barrier layers each of a compressive-strained material, said barrier material being a tensile-strained material.

22. The structure of claim 15, wherein said first barrier layer is disposed over said substrate, said quantum well layer is disposed over said first barrier layer and said second barrier layer is disposed over said quantum well layer, and further comprising:
at least one additional quantum well layer disposed over said second barrier layer, said at least one additional quantum well layer including indium, gallium, arsenic and nitrogen; and
at least one additional barrier layer of said barrier material and disposed over said at least one additional quantum well layer.

23. A semiconductor light-emitting structure, comprising:
a substrate including gallium arsenide, said substrate having a surface and a first lattice constant;
a quantum well layer of a material including indium, gallium, arsenic and nitrogen, said quantum well layer being disposed over the surface of said substrate and having a second lattice constant larger than said first lattice constant, said quantum well layer having opposing surfaces;
first and second barrier layers each of a material having a third lattice constant smaller than said first lattice constant, each of said first and second barrier layers being disposed adjacent to one of said opposing surfaces of said quantum well layer; and
first and second intermediate barrier layers each of a material having a fourth lattice constant larger than said first lattice constant, each of said first and second intermediate barrier layers being disposed between said quantum well layer and one of said first and second barrier layers;
wherein said structure is capable of emitting in the 1.2 μm to 1.6 μm range after annealing of said structure.

24. The structure of claim 23, wherein said first and second intermediate barrier layers are formed of a compressive-strained barrier material having a composition designed to minimize strain-related diffusion of nitrogen out of said quantum well layer.

25. The structure of claim 24, wherein said compressive-strained barrier material is selected from the group consisting of Group III-V nitrides, Group III-V phosphides, Group III-V arsenides, and Group III-V nitride phosphides.

26. The structure of claim 25, wherein said compressive-strained barrier material is selected from the group consisting of InGaP, InGaAsN, AlInGaP, InGaAsP, InGaAsPN, and AlInGaAsP.

27. The structure of claim 25, wherein said first and second barrier layers are of a tensile-strained material, said tensile-strained material being selected from the group consisting of GaAsP, GaAsPN, InGaP, InGaPN, AlInGaP, InGaAsP, InGaAsPN, AlInGaAsP, InGaAsN and GaAsN.

28. The structure of claim 23, wherein said first barrier layer is disposed over said substrate, said first intermediate barrier layer is disposed over said first barrier layer, said quantum well layer is disposed over said first intermediate barrier layer, said second intermediate barrier layer is disposed over said quantum well layer and said second barrier layer is disposed over said second intermediate barrier layer, and further comprising:
a second quantum well layer of a material having said second lattice constant disposed over said second barrier layer, said second quantum well layer including indium, gallium, arsenic and nitrogen;
a third barrier layer of a material having said third lattice constant and disposed over said second quantum well layer; and
third and fourth intermediate barrier layers each of a material having said fourth lattice constant, said third intermediate barrier layer being disposed between said second barrier layer and said second quantum well layer and said fourth intermediate barrier being disposed between said second quantum well layer and said third barrier layer.

29. A method of manufacturing a semiconductor light-emitting structure, comprising:
providing a substrate including gallium arsenide, said substrate having a surface; and
forming an active region over the surface of said substrate, the forming comprising:
forming a quantum well layer of a material including indium, gallium, arsenic and nitrogen, said quantum well layer having opposing surfaces, and
forming first and second barrier layers each of a barrier material including nitrogen in substantially the same concentration as in said quantum well layer, each of said first and second barrier layers being disposed adjacent to one of said opposing surfaces of said quantum well layer;
wherein said structure is capable of emitting in the 1.2 μm to 1.6 μm range after annealing of said structure.

30. A method of manufacturing a semiconductor light-emitting structure, comprising:
providing a substrate including gallium arsenide, said substrate having a surface, and
forming an active region over the surface of said substrate, the forming comprising:
forming a quantum well layer of a material including indium, gallium, arsenic and nitrogen, said quantum well layer having opposing surfaces, and
forming first and second barrier layers each of a barrier material containing at least two or more Group III elements in combination with nitrogen, each of said first and second barrier layers being disposed adjacent to one of said opposing surfaces of said quantum well layer;
wherein said structure is capable of emitting in the 1.2 μm to 1.6 μm range after annealing of said structure.

31. A method of manufacturing a semiconductor light-emitting structure, comprising:
providing a substrate including gallium arsenide, said substrate having a surface; and
forming an active region over the surface of said substrate, the forming comprising:
forming a quantum well layer of a material including indium, gallium, arsenic and nitrogen, said quantum well layer having opposing surfaces, and
forming first and second barrier layers each of a barrier material containing at least indium and gallium, each of said first and second barrier layers being disposed adjacent to one of said opposing surfaces of said quantum well layer;
wherein said structure is capable of emitting in the 1.2 μm to 1.6 μm range after annealing of said structure.

32. A method of manufacturing a semiconductor light-emitting structure, comprising:
providing a substrate including gallium arsenide, said substrate having a surface and a first lattice constant; and
forming an active region over the surface of said substrate, the forming comprising:
forming a quantum well layer of a material including indium, gallium, arsenic and nitrogen, said quantum well layer having a second lattice constant larger than said first lattice constant, said quantum well layer further having opposing surfaces,
forming first and second barrier layers each of a material having a third lattice constant smaller than said first lattice constant, each of said first and second barrier layers being disposed adjacent to one of said opposing surfaces of said quantum well layer, and
forming first and second intermediate barrier layers each of a material having a fourth lattice constant larger than said first lattice constant, each of said first and second intermediate barrier layers being disposed between said quantum well layer and one of said first and second barrier layers;
wherein said structure is capable of emitting in the 1.2 μm to 1.6 μm range after annealing of said structure.
